(19) United States
(12) Patent Application Publication
(10) Pub. No.: US 2023/0207755 A1
(43) Pub. Date: Jun. 29, 2023

(54) SPACER LED ARCHITECTURE FOR HIGH EFFICIENCY MICRO LED DISPLAYS

(71) Applicant: PLESSEY SEMICONDUCTORS LTD, Plymouth Devon (GB)

(72) Inventors: John Lyle Whiteman, Plymouth Devon (GB); Samir Mezouari, Plymouth Devon (GB)

(21) Appl. No.: 17/927,069

(22) PCT Filed: May 28, 2021
(86) PCT No.: PCT/GB2021/051327

§ 371 Date: Nov. 22, 2022

(30) Foreign Application Priority Data
Jun. 3, 2020 (GB) 2008329.0

(51) Int. Cl. H01L 33/60; H01L 33/32; H01L 33/22

(52) U.S. Cl. CPC H01L 33/60; H01L 33/32; H01L 33/22; H01L 27/156

(57) ABSTRACT

An optical device comprising a light emitting structure having substantially vertical sidewalls, the light emitting structure comprising an active layer, the active layer being configured to emit light when an electrical current is applied to the device; an electrically insulating, optically transparent spacer layer having an internal face facing the sidewalls of the light emitting structure and an opposing external face, wherein the spacer layer is configured to enhance light extraction from the active layer; and a reflective, electrically conducting mirror layer disposed on the external face of the spacer layer.

### FIELD OF THE INVENTION

The invention relates to arrays of light emitting devices and methods of forming arrays of light emitting devices. In particular, but not exclusively, the invention relates to arrays of light emitting devices with optimised light extraction.

### BACKGROUND OF THE INVENTION

It is known that light emitting diode (LED) devices provide efficient sources of light for a wide range of applications. Increases in LED light generation efficiency and extraction, along with the production of smaller LEDs (with smaller light emitting surface areas) and the integration of different wavelength LED emitters into arrays, has resulted in the provision of high quality colour arrays with multiple applications, in particular in display technologies.

Several display technologies are being considered and used for Micro LED Displays for use in various applications, including Augmented Reality, Merged Reality, Virtual Reality and Direct view displays, such as Smart Watches and Mobile devices. Technologies such as Digital Micro Mirrors (DMD) and Liquid Crystal on Silicon (LCoS) are based on reflective technologies, where an external light source is used to produce Red, Green and Blue photons in time sequential mode and the pixels either divert the light away from an optical element (DMD) or absorb light (LCoS) to adjust the brightness of a pixel in order to form an image. Liquid Crystal Displays (LCD) typically use a back light, an LCD panel on an addressable back plane and colour filters to produce an image. A back plane is required to turn individual pixels on and off and to adjust the brightness of individual pixels for each frame of video. Increasingly, emissive display technologies such as Organic Light Emitting Diode (OLED) or Active Matrix OLED (AMOLED) and more recently, Micro LED as they offer lower power consumption for untethered micro display applications and higher image contrast. Micro LED, in particular, offers higher efficiency and better reliability than micro OLED and AMOLED displays.

The invention being described in this document relates to a method for making a highly efficiency micro LED array combining techniques to improve Internal Quantum Efficiency (IQE) and Light Extraction Efficiency (LEE) to improve efficiency and brightness figures of merit.

Structures deigned to increase light extraction efficiency are well known in the LED industry, including the use of a pseudo parabolic shaped MESA, to direct photons, generated in the multiple quantum wells (MQW), to an emitting surface.

The technique used to fabricate a MESA with such a shape involves a technique such as Reactive Ion Etch (RIE) or Inductively Coupled Etch (ICP). In such etch techniques, a high energy plasma comprising RF, high voltage (DC bias) and reactive gases, often including free radicals, is used to selectively etch the semiconducting material. The features are defined using a photolithographic process using a photo sensitive material to define areas which will be subject to the etch process and area which will remain un-etched. The precise shape of the MESA can be controlled by the profile of the photo sensitive material used to define the pattern and by etch pressure, power, gas flow and gas species.

Not only does this complicate the manufacturing process, but as a result of this etch process, the edge of the MESA can become damaged which affects the IQE of the micro LED.

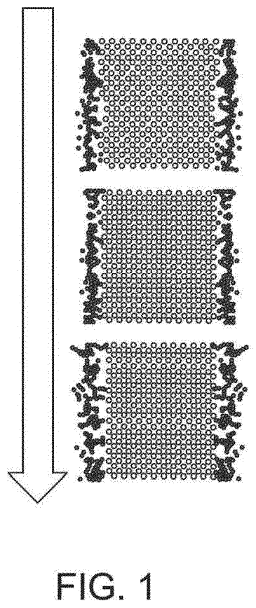

As shown in FIG. 1, as DC bias and Plasma density increases, more damage is done to the edge of the feature leading to surface leakage path formed by crystal damage, nitrogen vacancies and dangling bonds. Dry etching generates many crystal defects due to the high energy ion bombardment at the surface. Dangling bonds are easily oxidized and crystal damage generates many defect levels in the energy bands which act as carrier recombination centers at the surface, leading to non-radiative recombination.

The surface recombination velocity (non-radiative recombination velocity) is faster than the radiative recombination velocity in the bulk MQW, therefore the small micro LED is vulnerable to surface recombination and a consequential reduction in IQE.

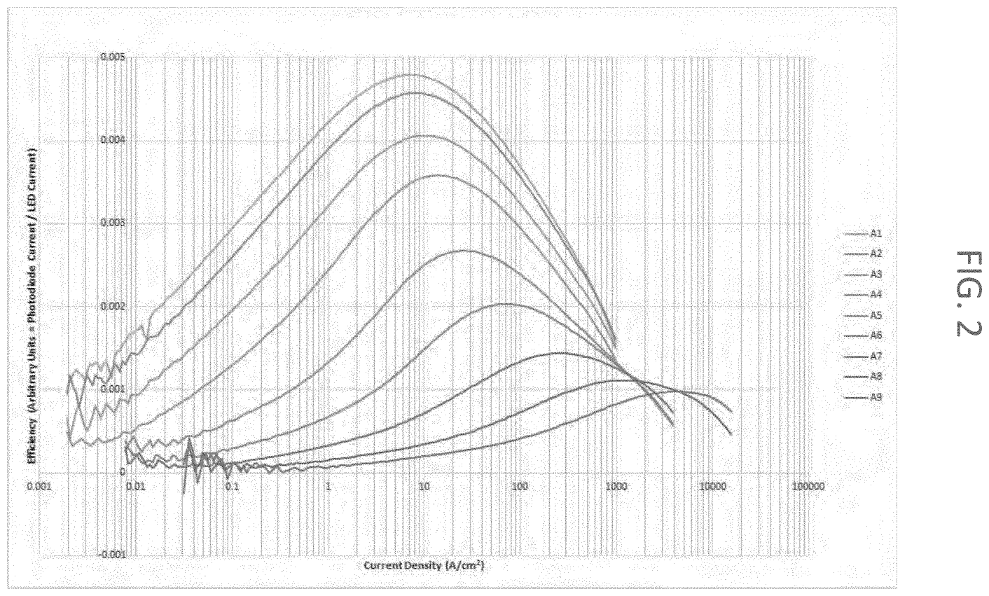

A widely reported consequence of the damage caused during MESA etch is efficiency reduction with smaller micro LED dimensions, as shown in FIG. 2. External Quantum Efficiency (EQE) is the product of IQE (the ratio of the number of photons generated to the number of electrons. The mechanism that drives this trend is the ratio of the perimeter of the micro LED to the area. As the micro LED reduces in size, the area of the sidewall increases in relation to the area of the MQWs so the surface leakage path at the edge of the micro LED causes increases in non-radiative recombination.

Micro LED displays used for augmented reality and Head Mounted Displays will operate at a current density of 1A/cm2 to 10A/cm2. This can imply a 20-fold reduction in efficiency of a small LED compared with a large LED.

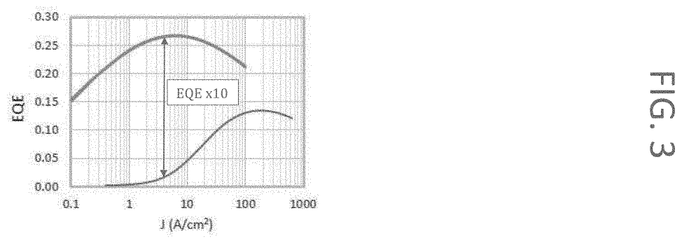

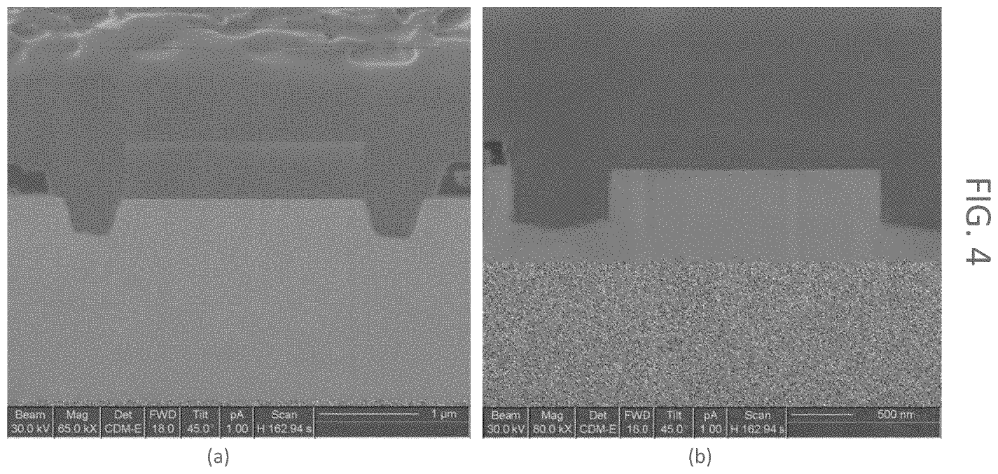

The efficiency of micro LEDs can be significantly increased by repairing the damage caused by the MESA etch, as shown in FIG. 3. It is typically possible to effect a 10-fold improvement in EQE by executing an optimized damage repair regime. The peak EQE increases after damage repair and the peak EQE occurs at a lower current density so that at the typical operating conditions, a 10-fold increase in efficiency can be obtained. Such a regime, is not compatible however with preserving a MESA shape which is optimized for high LEE, as the repair process removes the semiconductor material which is damaged by the MESA etch, as shown in FIG. 4.

### SUMMARY OF THE INVENTION

In order to mitigate for at least some of the above-described problems, there is provided an optical device in accordance with the appended claims. Further, there is provided an array of optical devices and a method of forming one or more optical devices in accordance with the appended claims.

In a first aspect of the invention, there is provided an optical device comprising a light emitting structure having substantially vertical sidewalls, the light emitting structure comprising an active layer, the active layer being configured to emit light when an electrical current is applied to the device; an electrically insulating, optically transparent spacer layer having an internal face facing the sidewalls of the light emitting structure and an opposing external face, wherein the spacer layer is configured to enhance light extraction from the active layer; and a reflective, electrically conducting mirror layer disposed on the external face of the spacer layer.

Advantageously, the spacer material acts as an optical component to enhance light extraction from the active layer of the light emitting structure, whilst the metallic material acts as mirror layer on the sides of the spacers further enhancing light extraction.

Preferably the optical device further comprises a passivation layer between the light emitting structure and the spacer layer.

Preferably the passivation layer is one of silicon dioxide, aluminium oxide or cubic aluminium nitride.

The passivation layer acts to reduce surface states that would otherwise degrade the electrical properties of the device.

Preferably the light emitting structure has a first light emitting surface, wherein the optical device further comprises a light extraction feature on the light emitting surface. The light extraction feature provides a further enhancement to the optical properties of the device.

Preferably the light extraction feature is in the form of a convex lens.

Preferably the convex lens has a radius of curvature of 3 microns. This has been found to provide the maximum light extraction.

Preferably the external face of the spacer layer has a pseudo parabolic or parabolic profile. The parabolic shape works to direct emitted photons towards the light emitting surface of the device such that they are incident on said surface at an angle of incidence below the critical angle, thereby allowing photons to be extracted into air at a high frequency.

Preferably the profile of the external face of the spacer layer approximates a Bézier curve having two control points with a Bézier coefficient of 0.5. This has been found to provide the maximum light extraction.

Preferably the spacer is one of silicon dioxide, silicon nitride or titanium oxide.

Preferably the light emitting structure further comprises an n-cladding layer, and wherein the mirror layer is in electrical contact with the n-cladding layer such that the mirror layer forms a first electrode of the optical device. Advantageously, the mirror layer further acts as a current spreading layer of the optical device.

Preferably the light emitting structure further comprises a p-cladding layer in electrical contact with a second electrode of the optical device.

Preferably the second electrode is formed on a second surface of the light emitting structure opposing the first surface, and wherein the second electrode is made from a reflective material. The arrangement of a reflective surface opposite the light emitting surface improves light extraction and thus the efficiency of the optical device.

Preferably the active layer comprises one or more quantum wells.

Preferably the light emitting structure further comprises a buffer layer and a super lattice.

Preferably the light emitting structure comprises indium gallium nitride.

Preferably the light emitting structure has one of a square, circular, triangular or pentagonal cross-section.

Preferably the light emitting structure has roughened sidewalls. This has been found to improve the luminance uniformity and further enhance light extraction.

Preferably the internal face of the spacer layer is formed of a first material and the external face of the spacer layer is formed of a second material. This allows for the use of materials with different indices of refraction, such that the emitted photons can be better directed towards the light emitting surface.

Preferably the first material has a higher index of refraction than the second material such that light is increasingly reflected back towards the light emitting surface of the light emitting structure.

In a second aspect of the invention, there is provided an array of the optical devices described above.

In a third aspect of the invention, there is provided a method of manufacturing the optical devices described above.

Further aspects of the invention will be apparent from the description and the appended claims.

### DETAILED DESCRIPTION OF AN EMBODIMENT OF THE INVENTION

A detailed description of embodiments of the invention is described, by way of example only, with reference to the figures, in which:

FIG. 1 shows a crystal damage to InGaN material with increasing plasma power and DC bias;

FIG. 2 shows external quantum efficiency (EQE) vs current density for micro LED sizes reducing from A1 (256 μm) to A9 (1 μm).

FIG. 3 shows the EQE of a micro LED with and without MESA damage reduction and repair.

FIG. 4 shows a cross section of an etched MESA, pre (a) and post (b) damage repair process.

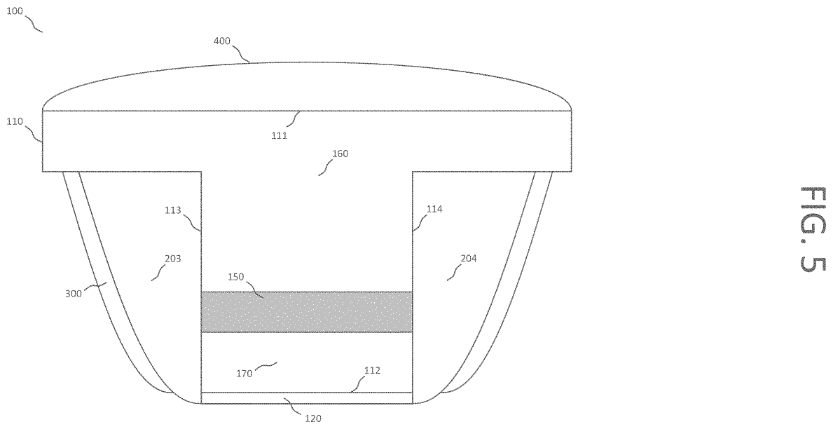

FIG. 5 shows an optical device according to an aspect of the present invention.

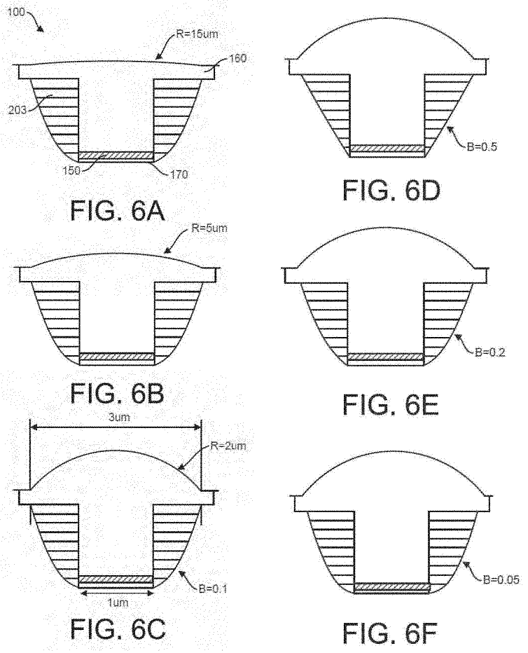

FIG. 6 shows a series of optical devices having differently shaped convex lenses and spacers as a function of radius of curvature R and Bézier coefficient B.

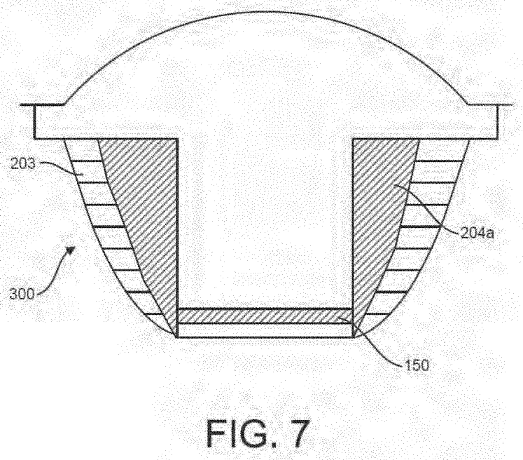

FIG. 7 shows an embodiment using two different spacer materials.

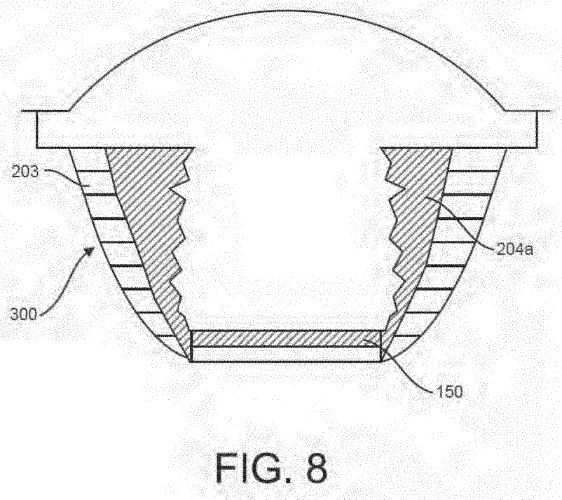

FIG. 8 shows and embodiment with roughened sidewalls.

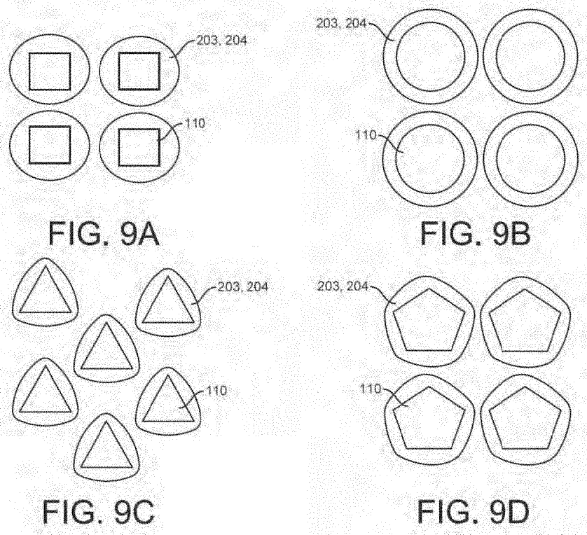

FIG. 9 shows embodiments wherein the light emitting structure has a square (a), circular (b), triangular (c) and pentagonal (d) cross-section.

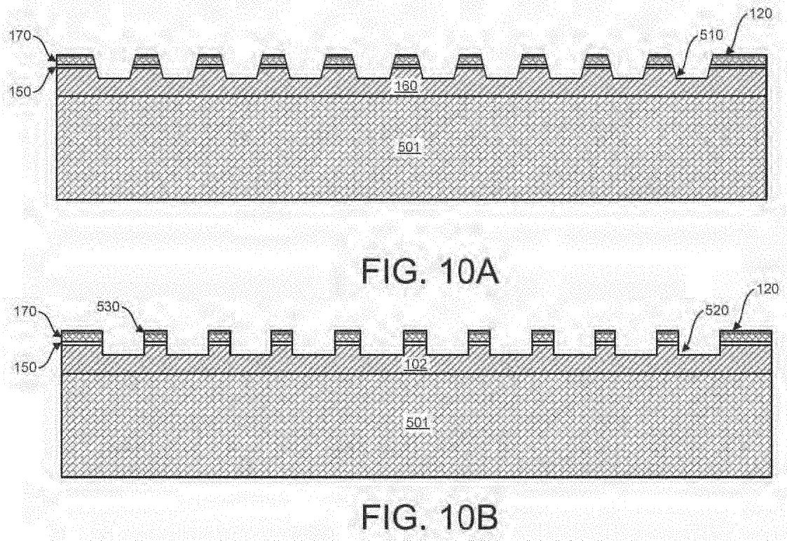

FIGS. 10-13 show the stages of the monolithic manufacturing process for the optical devices.

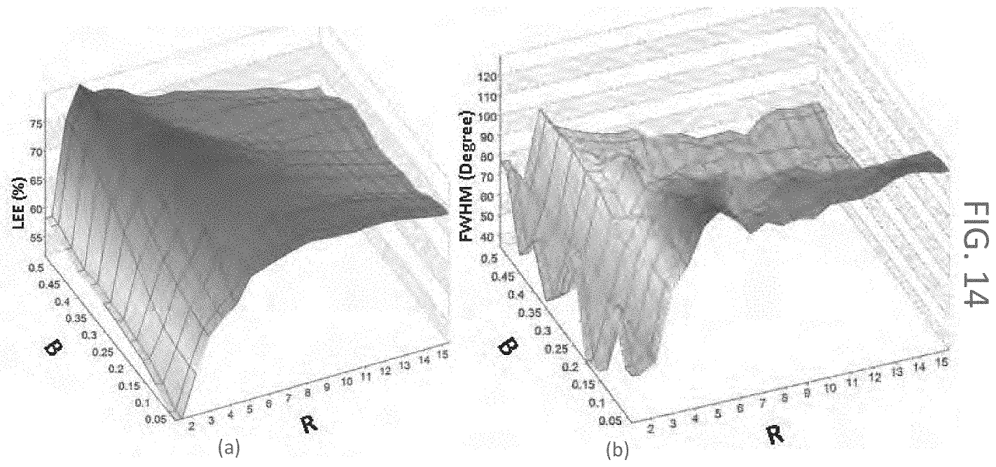

FIG. 14 shows the variation of (a) light extraction efficiency (LEE) and (b) emission angle at full-width half-maximum with radius of curvature R and Bézier coefficient B.

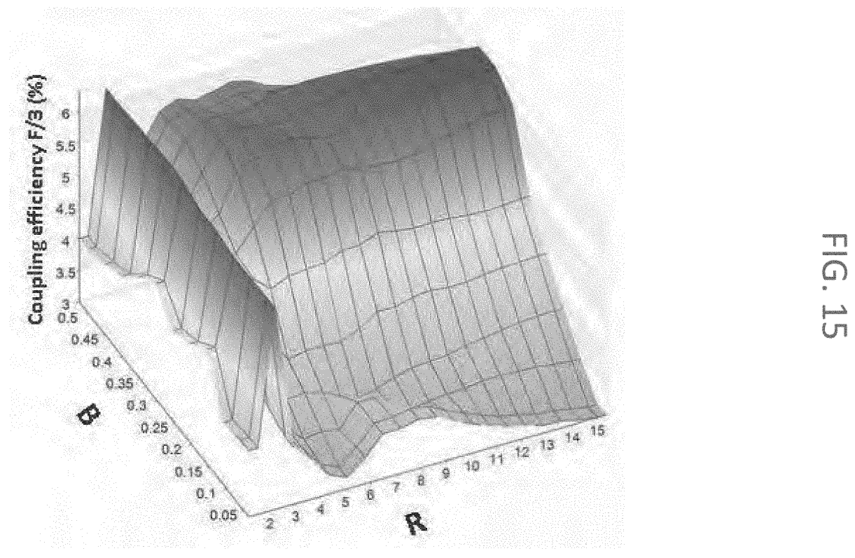

FIG. 15 shows the variation of coupling efficiency of F/3 projection lens with radius of curvature R and Bézier coefficient B.

FIG. 5 shows an optical device 100 formed by light emitting structure 110, the light emitting structure 110 having a light emitting top surface 111 and an opposing bottom surface 112 and substantially vertical sidewalls 113 and 114. In an alternative embodiment the light emitting structure 110 has roughened sidewalls as shown in FIG. 7, which act to improve luminance uniformity and enhance light extraction of the optical device 100.

In an embodiment, the light emitting structure 110 has one of a square, circular, triangular or pentagonal cross-section, as shown in FIG. 9.

The light emitting structure 110 sits on a reflective conducting layer (a p-contact layer) 120 forming an electrode and further includes an active layer 150 containing one or more quantum wells situated between an n-type region (or n-cladding layer) 160 and a p-type region (or p-cladding layer) 170 wherein the p-type region is in contact with the electrode/reflective conducting layer 120. In an embodiment, the n-type region 160 and p-type region 170 are n-doped and p-doped gallium nitride respectively. In a further embodiment, indium gallium nitride is used. The light emitting structure 110 is based on a typical LED structure. In further embodiments, alternative light emitting structures are used having alternative and/or additional layers. The skilled person would appreciate that any number of potential light emitting structures can be used providing they operate as described below. In a particular embodiment, the light emitting structure 110 includes an electron blocking layer situated between the p-type region 170 and the active layer 150. In a further embodiment, the light emitting structure 110 includes one or more buffer layers.

Whilst the n-type region 160 is n-doped GaN, in further examples, additionally, or alternatively, the n-type region 160 comprises different materials. Whilst the p-type region 170 is p-doped GaN, in further examples, additionally, or alternatively, the p-type region 170 comprises different materials.

In contact with sidewalls 113 and 114 are respective pseudo parabolic spacers 203 and 204 formed of silicon dioxide and having index of refraction n₁. In an alternative embodiment, the spacers are formed from silicon nitride or titanium oxide. Whilst the spacers have pseudo parabolic sides in the illustrated embodiment, the sides can have any suitable profile described by a range of Bézier curves having two control points and coefficients B—where B is one of 0.1, 0.5, 0.2 and 0.05 as depicted in FIG. 6(c)-(f) respectively. In a preferred embodiment, the Bézier coefficient is 0.5, resulting in approximately straight sided spacers as shown in FIG. 6(d). In a further embodiment, spacers 203 and 204 formed of an inner spacers 203a, 204a having index of refraction n₁ and outer spacers 203b, 204b having index of refraction n₂ as shown in FIGS. 7 and 8, which further improve luminance uniformity and further enhances light extraction from the active layer. In a preferred embodiment, n₁>n₂ which can be achieved by using silicon nitride as the inner spacer material and aluminium oxide as the second spacer material. In a further embodiment, additional spacer layers can used with a decreasing index of refraction away from the sidewalls of the light emitting structure (i.e. n₁>n₂>n_{N}). Whilst depicted as two separate spacers in schematic FIG. 5, the spacers are in fact a continuous layer, as shown in the cross-sectional views depicted in FIG. 9.

Coating the outer face of spacers 203 and 204 is a reflective metallic material which forms a mirror layer 300 and which further contacts n-type region 160 to form a second electrode of the optical device. In an embodiment, the mirror layer 300 is formed from aluminium and has a surface roughness of Ra=50 nm. In a preferred embodiment the mirror layer has a surface roughness of Ra<10 nm so as to prevent diffusion of light which reduces the light extraction efficiency of the device.

On the light emitting top surface 111 of the light emitting structure 110 is a light extraction feature 400 in the form of a convex lens. Whilst the lens depicted in FIG. 6(a) has a radius of curvature of 15 μm, alternative embodiment are shown in FIGS. 6(b) and (c), having radius of curvatures of 5 μm and 2 μm respectively. In a preferred embodiment, the lens has a radius of curvature of 3 μm.

In use, a current is applied between the electrodes, with the mirror layer 300 further operating as a current spreading layer. Light emitted by the active layer 150 is directed towards the light emitting top surface 111 either directly or i) via reflection from the reflective conducting layer 120, ii) via reflections and/or refractions at the spacers 203, 204 (and 203a, 204a if present), iii) via the mirror layer 300 formed by the reflective metallic material or iv) via multiple reflections within the structure including combinations of the above. Accordingly, the reflective conducting layer 120, spacers 203, 204 and mirror layer 300 are arranged to increase the proportion of light incident on the light emitting surface within the critical angular range to allow for transmission of light.

FIGS. 10-13 show the process for the creation of the optical devices illustrated in FIGS. 5-9. Whilst the Figures depict a monolithic array, the described process is also applicable to the creation of individual devices.

At the stage shown in FIG. 10(a), a light emitting structure 110 formed by an indium gallium nitride (GaN) LED is grown via known means on a substrate wafer 501 of <111> silicon, the LED structure having at least an n-cladding layer 160, an outer p-cladding layer 170 and an active layer 150 in between. A reflective p-contact layer 120 is deposited over the p-cladding layer 170 and a plurality of openings 510, one for each sub-pixel, are made in the p-contact 120 and GaN layers, exposing an underlying n-cladding layer 160 by way of a photo lithography followed by a reactive ion etch (RIE) or inductively coupled plasma (ICP) etch process. This produces an array of MESAs having generally sloped sidewalls with each mesa representing an individual light emitting structure 110 topped by a portion of the p-contact layer 120. In an embodiment, the etch is tuned to provide pseudo parabolic shaped sidewalls. Whilst described as being grown on a silicon wafer, the skilled person would appreciate that any suitable substrate could be used. In an embodiment, a sapphire substrate is employed. In a further embodiment, additional or alternative intervening layers are used in order to account for a lattice mismatch between the substrate and the subsequently grown layers, such as an aluminium nitride buffer layer. Equally, alternative or additional etch techniques could be utilised, provided they result in the array of MESAs as described.

As a result of the etch process, the MESA sidewalls contain damaged crystal structures which lead to surface leakage paths. To repair the damaged crystalline structure a repair process is applied which removes the damaged material to reveal good quality crystal structure with reduced dangling bonds and nitrogen vacancies. In an embodiment, this is achieved via a potassium hydroxide wet etch. In an alternative embodiment, the repair process includes consists of a wet etch using tetramethylammonium hydroxide. The opening sidewall profile is thus changed from being sloped or shaped, to being vertical 520—see FIG. 4.

Optionally, the surface roughness of the sidewalls can be tuned, either by performing a further dry etch, or by using a photolithographic resist with a suitable resist profile. Advantageously, substantially vertical, yet roughened sidewalls have been found to improve the luminance uniformity and enhance light extraction from the optical device.

At the stage shown in FIG. 10(b), a thin passivation layer 530, is deposited formed from silicon dioxide. In an alternative embodiment, the passivation layer is one of aluminium oxide or cubic aluminium nitride. The layer is deposited by known means.

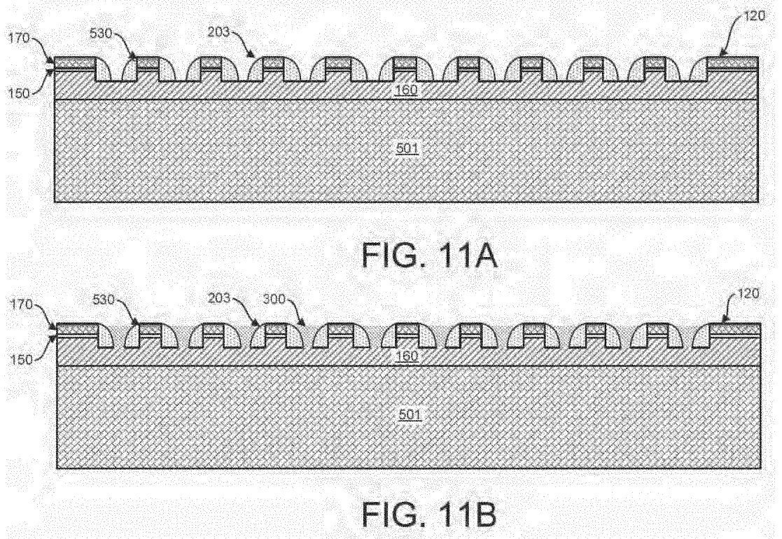

At the stage shown in FIG. 11(a), a conformal coating of silicon dioxide is deposited and the resulting film is etched back using RIE etch to form a uniform, pseudo parabolic spacer 203. In alternative embodiments, one of silicon nitride or titanium oxide are used as the spacer material. The skilled person would be aware that any suitably high index of refraction, non-conductive material may be used. The purpose of the spacer is to act as an optical component to enhance light extraction from the light emitting structure 110 into the spacers 203.

At the stage shown in FIG. 11(b), a layer of aluminium is deposited and patterned via established semiconductor techniques to form an ohmic contact to the n-cladding layer 160. This layer forms a common ohmic n-contact but also acts as a current spreading layer and as a mirror layer 300 on the sides of the spacers 203, leading to enhanced light extraction from the pixel.

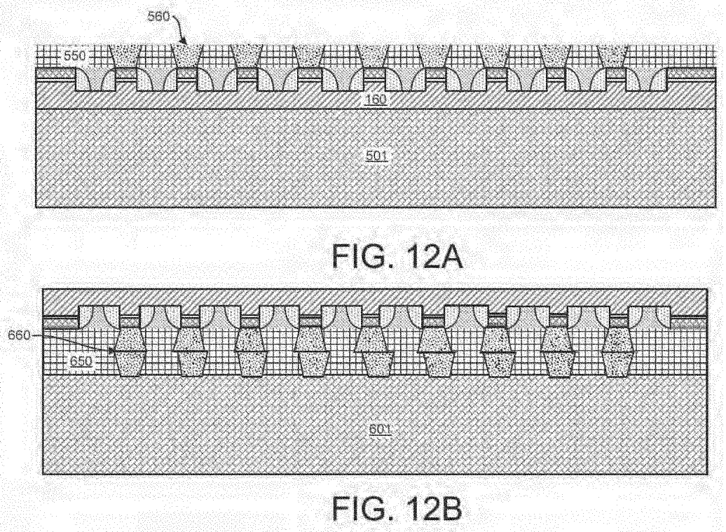

At the stage shown in FIG. 12(a), an insulating layer 550 of silicon oxide is deposited and chemical mechanically polished (CMP) to make the topography flat. In an alternative embodiment, silicon nitride is used. A plurality of openings is made using photolithography and RIE etch techniques to expose the underlying portions of the p-contact layer 120. A layer of metal 560 is then deposited via known manufacturing techniques. The deposited metal is subsequently polished via CMP to fill the openings — forming an ohmic contact to the p-contact layer 120 of each optical device 100.

At the stage shown in FIG. 12(b), a second wafer 601 having another later of silicon oxide 650 and corresponding metal deposits 660 is bonded to the growth surface of the wafer 501 and the growth substrate is removed. In an embodiment, the second wafer is a CMOS back plane. In an alternative embodiment, a silicon handle wafer is used. The metal deposits 660 of the second wafer 601 contact the corresponding metal portions 560 of the wafer 501.

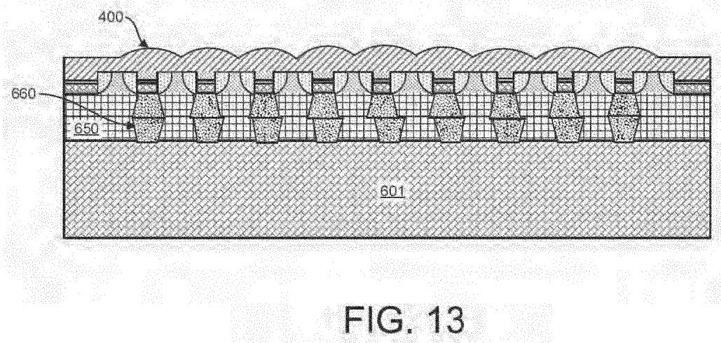

At the stage shown in FIG. 13, a plurality of light extraction features 400 are patterned into the surface of the GaN/n-cladding layer 160. In an embodiment, the light extraction features 400 are formed in a resin coating applied to the light emitting surface of the light emitting structure 110. In an alternative embodiment, the light extraction features 400 are formed by the growth material itself (i.e. the n-cladding layer 160). In a further embodiment, the surface is left flat, depending on the optical requirements of the optical device.

The resulting structure is an array of optical devices which uniquely combines high internal quantum efficiency and high light extraction efficiency.

Optical simulations are performed to study the light extraction efficiency as a function of the radius of curvature of the convex light extraction feature 400 and the shape of the mirror layer 300 (set by the profile of the spacers 203, 204). For each of these simulations, the light emitting structure 111 is modelled as a 3.5 μm pixel pitch die.

The light extraction efficiency versus both the radius of curvature and Bézier coefficient is shown in FIG. 14(a) using a silicon nitride spacer material. Preferably, silicon nitride is used due to its high index of refraction (2.05 at 450 nm wavelength) and ubiquity in the semiconductor industry. As can be seen, the maximum light extraction is achieved when the spacers 203, 304 (and thus the mirror layer 300) forms a straight wall shaped and the convex lens has a radius of curvature of 3 μm.

The corresponding emission angle at full-width half-maximum (FWHM) is shown in FIG. 14(b). As can be seen, the maximum LEE efficiency yield to a slightly narrower emission pattern with a FWHM is about 100 degrees compared to a Lambertian distribution (120 degrees).

Accordingly, a micro-LED array device formed in the manner described is particularly suitable for virtual and augmented reality systems where it is coupled to a projection lens system to form a virtual image perceived by the eye. Typically, the projection has an F-number between 1.5 and 4. In this analysis we have taken a projection lens of F-number 3 (F/30) and performed ray-tracing simulations. An F/3 projection lens has an acceptance angle of about +/−9 degrees, so light emitted outside this angular range is not coupled to the imaging optical path and therefore becomes undesirable stray-light within the system. The result of the optical simulations are shown in FIG. 15. In the above example, the maximum system coupling efficiency is achieved when the spacers 203, 204 (together with the mirror layer 300) form a straight wall shape with a Bézier coefficient of 0.5 and the convex lens has a radius of curvature of 2.3 μ, which corresponds to the lowest FWHM emission angle as shown in FIG. 14(b).

1. An optical device comprising:
a light emitting structure having substantially vertical sidewalls, the light emitting structure comprising an active layer, the active layer being configured to emit light when an electrical current is applied to the device;
an electrically insulating, optically transparent spacer layer having an internal face facing the sidewalls of the light emitting structure and an opposing external face, wherein the spacer layer is configured to enhance light extraction from the active layer; and
a reflective, electrically conducting mirror layer disposed on the external face of the spacer layer.

2. The optical device of claim 1 further comprising a passivation layer between the light emitting structure and the spacer layer.

3. The optical device of claim 2, wherein the passivation layer is one of silicon dioxide, aluminium oxide or cubic aluminium nitride.

4. The optical device of claim 1 wherein the mirror layer has a surface roughness of Ra=50 nm.

5. The optical device of claim 1 wherein the mirror layer has a surface roughness of Ra=10 nm.

6. The optical device of claim 1 wherein the light emitting structure has a first light emitting surface and wherein the optical device further comprises a light extraction feature on the light emitting surface.

7. The optical device of claim 6 wherein the light extraction feature is in the form of a convex lens.

8. The optical device of claim 7 wherein the convex lens has a radius of curvature of one of 2.3 microns or 3 microns.

9. The optical device of claim 1 wherein the external face of the spacer layer has a pseudo parabolic or parabolic profile.

10. The optical device of claim 9, wherein the profile of the external face of the spacer layer approximates a Bézier curve having two control points with a Bézier coefficient of 0.5.

11. The optical device of claim 1 wherein the spacer layer is formed of any one of silicon dioxide, silicon nitride or titanium oxide.

12. The optical device of claim 1 wherein the light emitting structure further comprises an n-cladding layer, and wherein the mirror layer is in electrical contact with the n-cladding layer such that the mirror layer forms a first electrode of the optical device.

13. The optical device of claim 1 wherein the light emitting structure further comprises a p-cladding layer in electrical contact with a second electrode of the optical device.

14. The optical device of claim 13 wherein the second electrode is formed on a second surface of the light emitting structure opposing the first light emitting surface, and wherein the second electrode is made from a reflective material.

15. The optical device of claim 1 wherein the light emitting structure further comprises a buffer layer and a super lattice.

16. The optical device of claim 1 wherein light emitting structure comprises indium gallium nitride.

17. The optical device of claim 1 wherein the light emitting structure has one of a square, circular, triangular or pentagonal cross-section.

18. The optical device of claim 1 wherein the light emitting structure has roughened sidewalls.

19. The optical device of claim 1 wherein the internal face of the spacer layer is formed of a first material and the external face of the spacer layer is formed of a second material.

20. The optical device of claim 19 wherein the first material has a higher index of refraction than the second material.

21. An array of two or more of the optical device of claim 1.

22. A method of manufacturing the optical device of claim 1.
